(19) United States
(12) Patent Application Publication
(10) Pub. No.: US 2026/0047038 A1
(43) Pub. Date: Feb. 12, 2026

(54) WATERFALL VERTICAL COLD PLATE

(71) Applicant: Vertiv Corporation, Westerville, OH (US)

(72) Inventors: Nigel Philip GORE, Old Windsor (GB); Brad Lee WILSON, Centennial, WY (US)

(21) Appl. No.: 19/297,180

(22) Filed: Aug. 12, 2025

Related U.S. Application Data
(60) Provisional application No. 63/682,138, filed on Aug. 12, 2024.

(51) Int. Cl. H05K 7/20; H05K 1/02; H05K 1/14

(52) U.S. Cl. CPC H05K 7/20254; H05K 1/0203; H05K 1/141; H05K 7/20327

(57) ABSTRACT

A system for processor cooling includes: at least one motherboard; at least one daughterboard disposed on the at least one motherboard; at least one cold plate disposed on the at least one daughterboard; at least one processor disposed on the at least one daughterboard; and at least one enclosure disposed on the at least one cold plate proximate the at least one processor on a side of the at least one processor opposite the at least one daughterboard, wherein the at least one enclosure is configured to direct a flow of a cooling fluid to cool the at least one processor.

### CROSS REFERENCE TO RELATED APPLICATIONS

This U.S. Non-Provisional Patent Applications claims the benefit of and priority to U.S. Provisional Patent Application Ser. No. 63/682,138 filed Aug. 12, 2024, the contents of which are incorporated herein by reference in its entirety.

### TECHNICAL FIELD

This disclosure relates to circuit cooling, and, in particular, to systems and methods for providing a waterfall vertical cold plate.

### BACKGROUND

Increasingly, computer processors, and accordingly, computing processing loads, require increased cooling capabilities to ensure such computing processors are properly cooled during operation. There are multiple important operational features of any cooling system, including providing the proper amount of cooling, such that the temperature is well maintained. This can be a supplied air temperature, the temperature of a supply or return fluid (e.g., such as air, water or refrigerant), or the temperature of a cold plate or heatsink.

### SUMMARY

An aspect of the disclosed embodiment includes a system for processor cooling. The system includes: at least one motherboard; at least one daughterboard disposed on the at least one motherboard; at least one cold plate disposed on the at least one daughterboard; at least one processor disposed on the at least one daughterboard; and at least one enclosure disposed on the at least one cold plate proximate the at least one processor on a side of the at least one processor opposite the at least one daughterboard, wherein the at least one enclosure is configured to direct a flow of a cooling fluid to cool the at least one processor.

Another aspect of the disclosed embodiments includes an apparatus for processor cooling. The apparatus includes: a motherboard having at least one daughterboard disposed thereon; a cold plate disposed on the at least one daughterboard; at least one processor disposed on the at least one daughterboard between the cold plate and the at least one daughterboard; and an enclosure disposed on the cold plate proximate the at least one processor on a side of the at least one processor opposite the at least one daughterboard, wherein the at least one enclosure is configured to direct a flow of a cooling fluid to cool the at least one processor.

Another aspect of the disclosed embodiments includes a cold plate for processor cooling that includes an enclosure having a vertical partition configured to allow the cooling fluid to enter on a first side of the vertical partition proximate a first side of the enclosure opposite a second side of the enclosure proximate a at least one processor disposed on a daughterboard, wherein the enclosure is configured to direct the cooling fluid along the first side of the enclosure in a first direction, and direct the cooling fluid, after directing the cooling fluid along the first side of the enclosure in the first direction, along the second side of the enclosure in a second direction, and wherein the second direction is in a direction 180 degrees relative to the first direction.

These and other aspects of the present disclosure are disclosed in the following detailed description of the embodiments, the appended claims, and the accompanying figures.

### BRIEF DESCRIPTION OF THE DRAWINGS

The above and/or other aspects will become apparent and more readily appreciated from the following description of example embodiments, taken in conjunction with the accompanying drawings, in which:

FIG. 1 generally illustrates a horizontally arranged motherboard and cold plates, according to the principles of the present disclosure.

FIG. 2 generally illustrates a vertically arranged motherboard, daughterboard, and cold plates, according to the principles of the present disclosure.

FIGS. 3-5 generally illustrate a waterfall vertical cold plate, according to the principles of the present disclosure.

FIG. 6 generally illustrates an alternative waterfall vertical cold plate, according to the principles of the present disclosure.

### DETAILED DESCRIPTION

Reference will now be made in detail to example embodiments which are illustrated in the accompanying drawings, wherein like reference numerals refer to like elements throughout. In this regard, the example embodiments may have different forms and may not be construed as being limited to the descriptions set forth herein.

It will be understood that the terms “include,” “including,” “comprise,” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be further understood that, although the terms “first,” “second,” “third,” etc., may be used herein to describe various elements, components, regions, layers and/or sections, these elements, components, regions, layers and/or sections may not be limited by these terms. These terms are only used to distinguish one element, component, region, layer or section from another element, component, region, layer or section.

As used herein, the term “and/or” includes any and all combinations of one or more of the associated listed items. Expressions such as “at least one of,” when preceding a list of elements, modify the entire list of elements and do not modify the individual elements of the list.

Various terms are used to refer to particular system components. Different companies may refer to a component by different names - this document does not intend to distinguish between components that differ in name but not function.

Matters of these example embodiments that are obvious to those of ordinary skill in the technical field to which these example embodiments pertain may not be described herein in detail.

It may be understood that the example embodiments described herein may be considered in a descriptive sense only and not for purposes of limitation. Descriptions of features or aspects within each example embodiment may be considered as available for other similar features or aspects in other example embodiments.

As described, increasingly, computer processors, and accordingly, computing processing loads, require increased cooling capabilities to ensure such computing processor are properly cooled during operation. There are multiple important operational features of any cooling system, including providing the proper amount of cooling, such that the temperature is well maintained. This can be a supplied air temperature, the temperature of a supply or return fluid (e.g., such as air, water or refrigerant), or the temperature of a cold plate or heatsink.

As central processing units (CPUs) and graphic processing units (GPUs) advance in technology, such CPUs and GPUs consume increasing amounts of electricity, generates heat as the electricity is consumed. Typically, in server computing devices or other suitable computing devices, most generated heat is transferred to air and exhausted. As chip densities increase, the practicality of continuing to use air is diminishing. Air, which is an insulator, does not have the thermal capacity to absorb and remove the amount of heat required to maintain the computer case temperatures needed for efficient processor operation.

As computing technology continues to evolve, processors are being converted to liquid cooling to remove heat more efficiently. This can be either single phase liquids (e.g., water and glycol mix), or two-phase refrigerants that provide additional advantages due to the latent heat of vaporization (e.g., which allows for increased thermal transfer as the refrigerants boil). Typically, the liquid is circulated through devices referred to as cold plates. A cold plate is comprised of a metal plate, usually copper or other suitable material, which is close coupled to the processor via pressure and a thermal interface material (TIM). The cold plate typically includes an enclosure on the opposite side from the processor through which the liquid is circulated. As the fluid flows through the enclosure, it absorbs heat transferred to the metal plate by the processor, and the heat is subsequently removed from the server through the fluid flow.

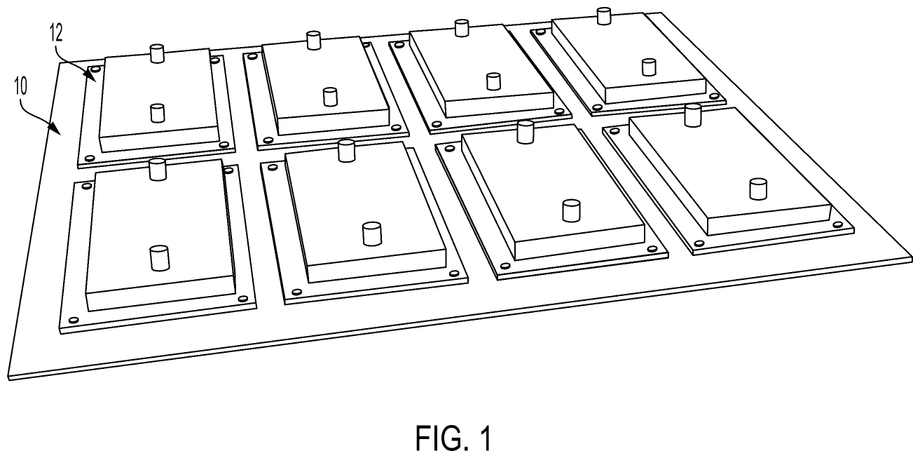

With the advent of high performance compute (HPC) and the use of GPUs, new compute topologies are being used for the processing of artificial intelligence (AI) workloads. When AI clusters are in ‘learning’ mode, they require many GPUs to be in very close proximity of each other for efficient processing. Current state of the art may include 8 GPU processors in close proximity on one computing motherboard. For example, as is generally illustrated in FIG. 1, a motherboard 10 may include a plurality of processors 12 disposed in a parallel plane relative to the motherboard 10.

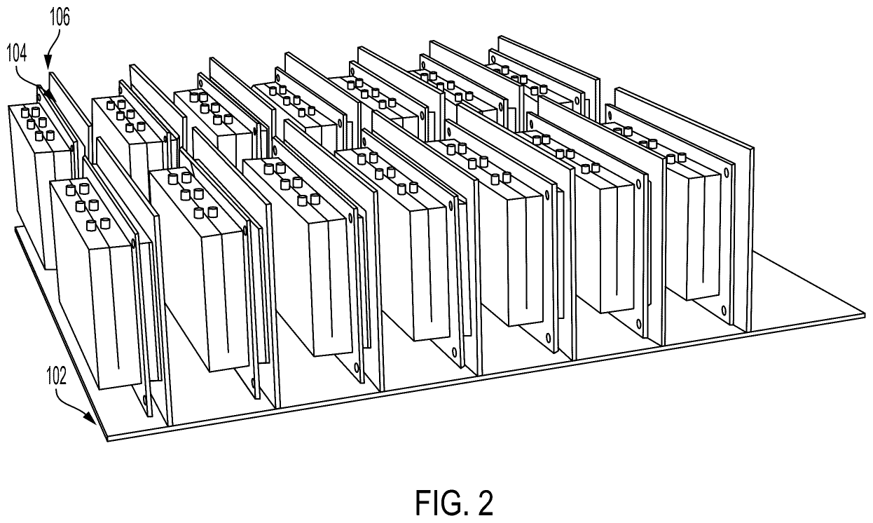

Alternatively, as is generally illustrated in FIG. 2, a motherboard 102 may include a plurality of the processors 104 (e.g., GPUs or other suitable processors) disposed on respective daughterboards 106 and in a plane perpendicular to the motherboard 102 (e.g., which may allow for additional processors 104 to be disposed in closer proximity to each other). In such an arrangement, a typical cold plate designed for horizontal application will not function efficiently due to the effects of gravity.

Accordingly, systems and methods, such as those described herein, configured to provide improve processor cooling in a vertical arrangement, may be desirable. In some embodiments, the systems and methods described herein may be configured to provide a cold plate designed to operate in a vertical plane.

The systems and methods described herein may be configured to drop fluid in at a top portion of the cold pate, relying on a ‘waterfall effect’ of fluid flowing towards a bottom of the cold plate. An internal partition may be configured to separate the ‘falling’ cold side from the ‘rising’ hot side. As the fluid warms, the fluid rises again, promoting mixing and agitation, thus promoting turbulent contact with the heated side. As the fluid nucleates to gas, it may be drawn off of the top on the side closest to the heated side in contact with the chip.

Additionally, or alternatively, the fluid may be impinged directly through the partition such that the impingement may target specific ‘hot zones’ on the processor. The systems and methods described herein may be configured to provide a cold plate for use in a vertical orientation that does not succumb to inefficiency due to the effects of gravity.

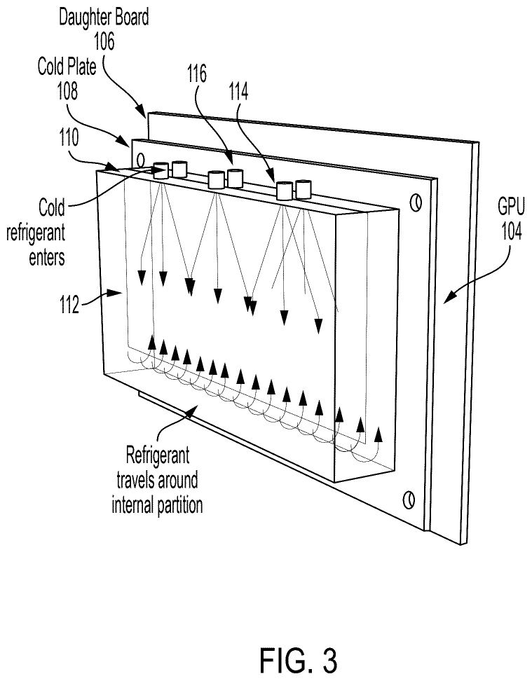

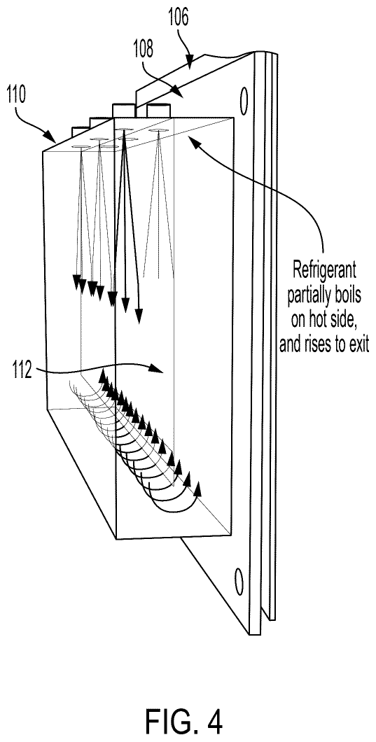

FIGS. 3 and 4, generally illustrate a cold plate 108 adapted to circulate either single-phase liquids (e.g., a liquid coolant that absorbs heat via convection) or two-phase liquids (e.g., a liquid coolant comprising a dielectric refrigerant with a relatively low boiling temperature) to processors 104 oriented in a vertical plane and disposed on a daughterboard 106. An enclosure 110, through which the fluids flow, may include a vertical partition 112 such that cold fluids enter the enclosure 110, via one or more inlets 114, on the side of the partition 112 furthest from the processor 104. The fluid may travel down (e.g., toward the motherboard 102) that side of the enclosure 110, turn 180 degrees, and travel up (e.g., away from the motherboard 102) a side of the enclosure 110 closest to the processor 104.

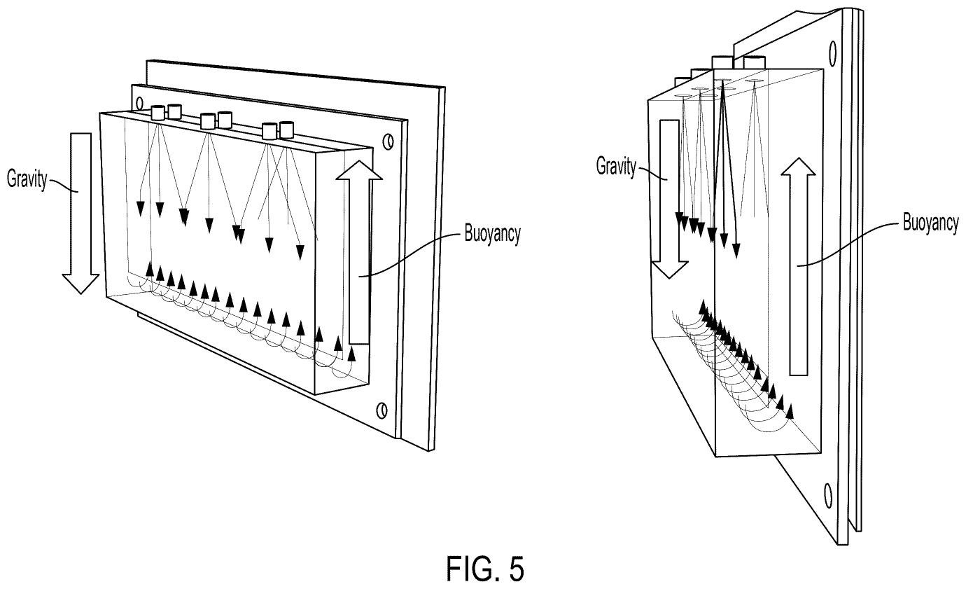

The pressure from pumping the fluids, because the fluid is traveling up during the heating process, ensures that the buoyancy effect will work with the fluid flow, as the hotter fluids will rise relative to cooler fluids. Further, in two-phase systems, the gaseous ‘bubbles’ will also rise toward one or more exits 116 (e.g., disposed on a portion of the enclosure 110 opposite the motherboard 102 or in any suitable location) naturally once the fluids boil. As is generally illustrated in FIG. 5, cold refrigerant enters via the inlets 114, drops, and is heated as it rises against the chip-side of the cold plate 108.

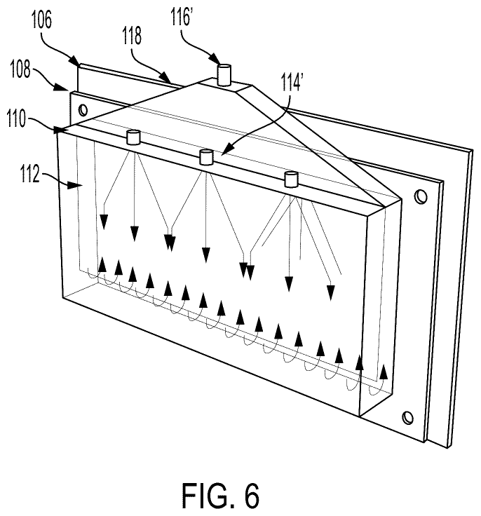

FIG. 6 generally illustrates an alternative configuration of the cold plate 108. As is generally illustrated, the enclosure 110 may include inlets 114′ and a tapered portion 118 that includes an exit 116′. The tapered portion 118 may allow fluid to exit via the single exit 116′, reducing or eliminating stagnant dead zones.

In some embodiments, a system for processor cooling includes: at least one motherboard; at least one daughterboard disposed on the at least one motherboard; at least one cold plate disposed on the at least one daughterboard; at least one processor disposed on the at least one daughterboard; and at least one enclosure disposed on the at least one cold plate proximate the at least one processor on a side of the at least one processor opposite the at least one daughterboard, wherein the at least one enclosure is configured to direct a flow of a cooling fluid to cool the at least one processor.

In some embodiments, the at least one processor includes a graphics processing unit. In some embodiments, the at least one enclosure includes a vertical partition configured to allow the cooling fluid to enter on a first side of the vertical partition proximate a first side of the at least one enclosure opposite a second side of the at least one enclosure proximate the at least one processor. In some embodiments, the at least one enclosure is configured to direct the cooling fluid along the first side of the at least one enclosure in a first direction. In some embodiments, the at least one enclosure is configured to direct the cooling fluid, after directing the cooling fluid along the first side of the at least one enclosure in the first direction, along the second side of the at least one enclosure in a second direction. In some embodiments, the second direction is in a direction 180 degrees relative to the first direction. In some embodiments, the cooling fluid includes a single-phase cooling fluid. In some embodiments, the cooling fluid includes a two-phase cooling fluid. In some embodiments, the at least one daughterboard is perpendicularly disposed on the at least one motherboard.

In some embodiments, an apparatus for processor cooling includes: a motherboard having at least one daughterboard disposed thereon; a cold plate disposed on the at least one daughterboard; at least one processor disposed on the at least one daughterboard between the cold plate and the at least one daughterboard; and an enclosure disposed on the cold plate proximate the at least one processor on a side of the at least one processor opposite the at least one daughterboard, wherein the at least one enclosure is configured to direct a flow of a cooling fluid to cool the at least one processor.

In some embodiments, the at least one processor includes a graphics processing unit. In some embodiments, the enclosure includes a vertical partition configured to allow the cooling fluid to enter on a first side of the vertical partition proximate a first side of the enclosure opposite a second side of the enclosure proximate the at least one processor. In some embodiments, the enclosure is configured to direct the cooling fluid along the first side of the enclosure in a first direction. In some embodiments, the enclosure is configured to direct the cooling fluid, after directing the cooling fluid along the first side of the enclosure in the first direction, along the second side of the enclosure in a second direction. In some embodiments, the second direction is in a direction 180 degrees relative to the first direction. In some embodiments, the cooling fluid includes a single-phase cooling fluid. In some embodiments, the cooling fluid includes a two-phase cooling fluid. In some embodiments, the at least one daughterboard is perpendicularly disposed on the at least one motherboard.

In some embodiments, a cold plate for processor cooling includes an enclosure having a vertical partition configured to allow the cooling fluid to enter on a first side of the vertical partition proximate a first side of the enclosure opposite a second side of the enclosure proximate a at least one processor disposed on a daughterboard, wherein the enclosure is configured to direct the cooling fluid along the first side of the enclosure in a first direction, and direct the cooling fluid, after directing the cooling fluid along the first side of the enclosure in the first direction, along the second side of the enclosure in a second direction, and wherein the second direction is in a direction 180 degrees relative to the first direction.

In some embodiments, the daughterboard is perpendicularly disposed on corresponding motherboard.

While example embodiments have been described with reference to the figures, it will be understood by those of ordinary skill in the art that various changes in form and details may be made therein without departing from the spirit and scope as defined by the following claims.

What is claimed is:

1. A system for processor cooling, the system comprising:
at least one motherboard;
at least one daughterboard disposed on the at least one motherboard;
at least one cold plate disposed on the at least one daughterboard;
at least one processor disposed on the at least one daughterboard; and
at least one enclosure disposed proximate the at least one processor on a side of the at least one processor opposite the at least one daughterboard, wherein the at least one enclosure is configured to direct a flow of a cooling fluid to cool the at least one processor.

2. The system of claim 1, wherein the at least one processor includes a graphics processing unit.

3. The system of claim 1, wherein the at least one enclosure includes a vertical partition configured to allow the cooling fluid to enter on a first side of the vertical partition proximate a first side of the at least one enclosure opposite a second side of the at least one enclosure proximate the at least one processor.

4. The system of claim 3, wherein the at least one enclosure is configured to direct the cooling fluid along the first side of the at least one enclosure in a first direction.

5. The system of claim 4, wherein the at least one enclosure is configured to direct the cooling fluid, after directing the cooling fluid along the first side of the at least one enclosure in the first direction, along the second side of the at least one enclosure in a second direction.

6. The system of claim 5, wherein the second direction is in a direction 180 degrees relative to the first direction.

7. The system of claim 1, wherein the cooling fluid includes a single-phase cooling fluid.

8. The system of claim 1, wherein the cooling fluid includes a two-phase cooling fluid.

9. The system of claim 1, wherein the at least one daughterboard is perpendicularly disposed on the at least one motherboard.

10. An apparatus for processor cooling, the apparatus comprising:
a motherboard having at least one daughterboard disposed thereon;
a cold plate disposed on the at least one daughterboard;
at least one processor disposed on the at least one daughterboard between the cold plate and the at least one daughterboard; and
at least one enclosure disposed on the cold plate proximate the at least one processor on a side of the at least one processor opposite the at least one daughterboard, wherein the at least one enclosure is configured to direct a flow of a cooling fluid to cool the at least one processor.

11. The apparatus of claim 10, wherein the at least one processor includes a graphics processing unit.

12. The apparatus of claim 10, wherein the enclosure includes a vertical partition configured to allow the cooling fluid to enter on a first side of the vertical partition proximate a first side of the enclosure opposite a second side of the enclosure proximate the at least one processor.

13. The apparatus of claim 12, wherein the enclosure is configured to direct the cooling fluid along the first side of the enclosure in a first direction.

14. The apparatus of claim 13, wherein the enclosure is configured to direct the cooling fluid, after directing the cooling fluid along the first side of the enclosure in the first direction, along the second side of the enclosure in a second direction.

15. The apparatus of claim 14, wherein the second direction is in a direction 180 degrees relative to the first direction.

16. The apparatus of claim 10, wherein the cooling fluid includes a single-phase cooling fluid.

17. The apparatus of claim 10, wherein the cooling fluid includes a two-phase cooling fluid.

18. The apparatus of claim 10, wherein the at least one daughterboard is perpendicularly disposed on the motherboard.

19. A cold plate for processor cooling, the cold plate comprising:
an enclosure having a vertical partition configured to allow cooling fluid to enter on a first side of the vertical partition proximate a first side of the enclosure opposite a second side of the enclosure proximate a at least one processor disposed on a daughterboard,
wherein the enclosure is configured to direct the cooling fluid along the first side of the enclosure in a first direction, and direct the cooling fluid, after directing the cooling fluid along the first side of the enclosure in the first direction, along the second side of the enclosure in a second direction, and
wherein the second direction is in a direction 180 degrees relative to the first direction.

20. The cold plate of claim 19, wherein the daughterboard is perpendicularly disposed on corresponding motherboard.
